(19) United States
(12) Patent Application Publication
(10) Pub. No.: US 2025/0254979 A1
(43) Pub. Date: Aug. 7, 2025

(54) CAPACITOR STRUCTURE

(71) Applicant: Winbond Electronics Corp., Taichung City (TW)

(72) Inventors: Jin-Neng Wu, Kaohsiung City (TW); Shih-Han Hung, Tainan City (TW)

(73) Assignee: Winbond Electronics Corp., Taichung City (TW)

(21) Appl. No.: 18/890,707

(22) Filed: Sep. 19, 2024

(30) Foreign Application Priority Data
Feb. 2, 2024 (TW) 113104186

(51) Int. Cl. H01L 27/08; H01L 25/065; H01L 27/10

(52) U.S. Cl. CPC H10D 84/212; H01L 25/0657; H10D 84/206

(57) ABSTRACT

A capacitor structure includes a first capacitor device structure, a first circuit layer, and at least one second capacitor device structure. The first capacitor device structure includes a first substrate and first capacitors. The first capacitors are located in the first substrate. The first circuit layer is located on the first capacitor device structure. The at least one second capacitor device structure is located on the first circuit layer. The second capacitor device structure includes a second substrate and second capacitors. The second capacitors are located in the second substrate. The first capacitors and the second capacitors are connected in parallel by the first circuit layer.

### CROSS-REFERENCE TO RELATED APPLICATION

This application claims the priority benefit of Taiwan application serial no. 113104186, filed on Feb. 2, 2024. The entirety of the above-mentioned patent application is hereby incorporated by reference herein and made a part of this specification.

### BACKGROUND

### Technical Field

The disclosure relates to a semiconductor structure, and in particular to a capacitor structure.

### Description of Related Art

A capacitor is a semiconductor device widely used in electronic products. However, under the circumstance that the size of the capacitor continues to shrink, how to further improve the capacitance of the capacitor structure has become a goal to continue making efforts.

### SUMMARY

The disclosure provides a capacitor structure, which can effectively increase the capacitance of the capacitor structure.

The disclosure a capacitor structure which includes a first capacitor device structure, a first circuit layer, and at least one second capacitor device structure. The first capacitor device structure includes a first substrate and multiple first capacitors. The first capacitors are located in the first substrate. The first circuit layer is located on the first capacitor device structure. The at least one second capacitor device structure is located on the first circuit layer. The second capacitor device structure includes a second substrate and multiple second capacitors. The second capacitors are located in the second substrate. The first capacitors and the second capacitors are connected in parallel by the first circuit layer.

Based on the above, in the capacitor structure provided by the disclosure, the first capacitor device structure and the second capacitor device structure are stacked, and the first capacitors of the first capacitor device structure and the second capacitors of the second capacitor device structure are connected in parallel by the first circuit layer, thereby effectively increasing the capacitance of the capacitor structure. In addition, the first capacitor is embedded in the first substrate and the second capacitor is embedded in the second substrate, so the collapse of the first capacitor and the second capacitor may be prevented. Furthermore, since the manufacturing process of the capacitor structure is simple, the manufacturing process complexity may be effectively reduced.

In order to make the aforementioned features and advantages of the disclosure comprehensible, embodiments accompanied with drawings are described in detail below.

### BRIEF DESCRIPTION OF THE DRAWINGS

FIG. 1A to FIG. 1J are cross-sectional views of a manufacturing process of a capacitor structure according to some embodiments of the disclosure.

FIG. 2 is a perspective view of a region R1 in FIG. 1B.

### DESCRIPTION OF THE EMBODIMENTS

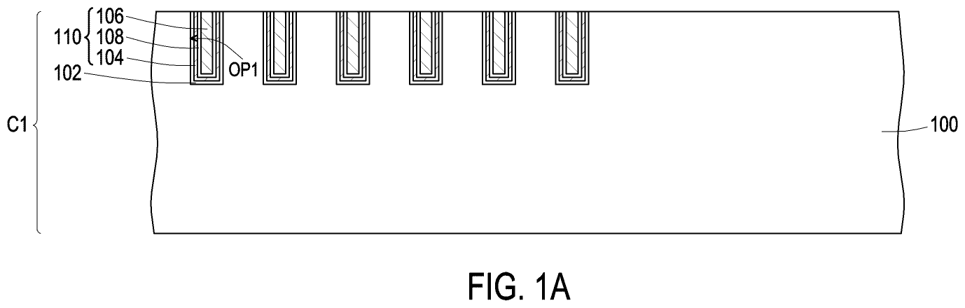

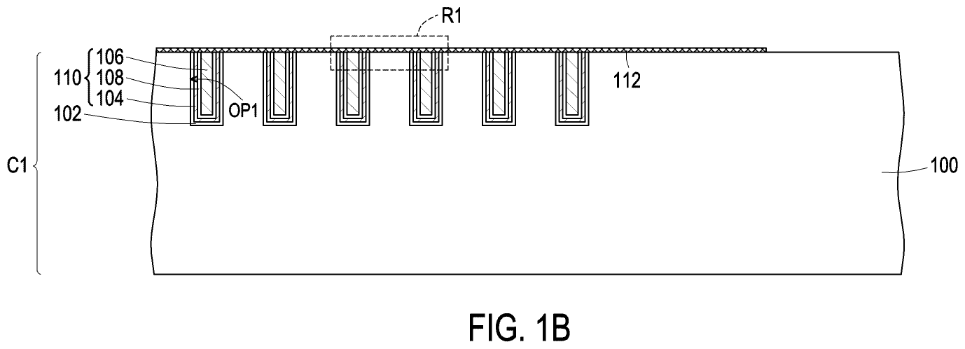

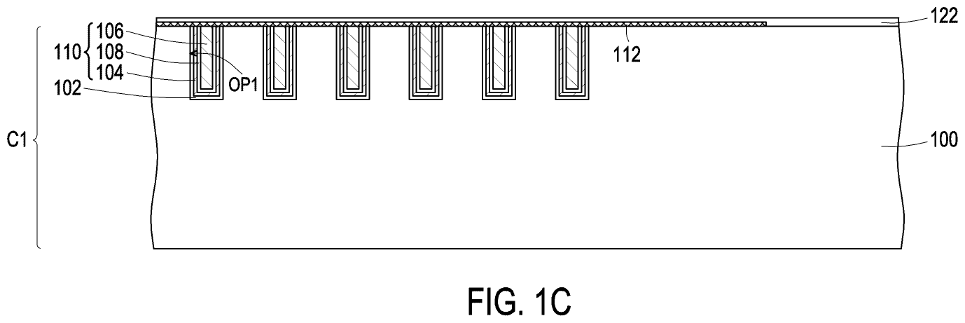

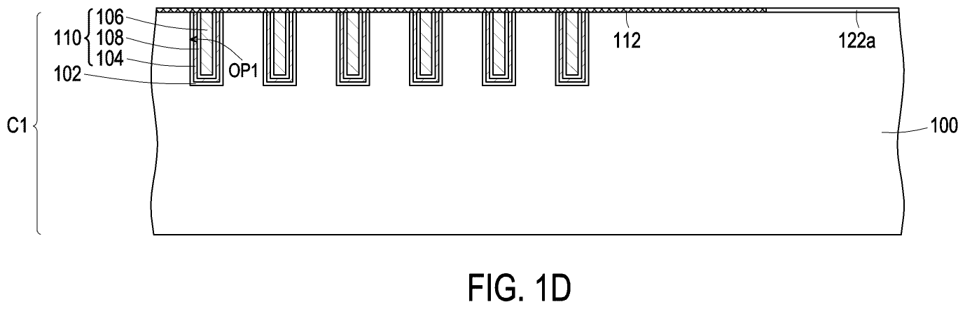

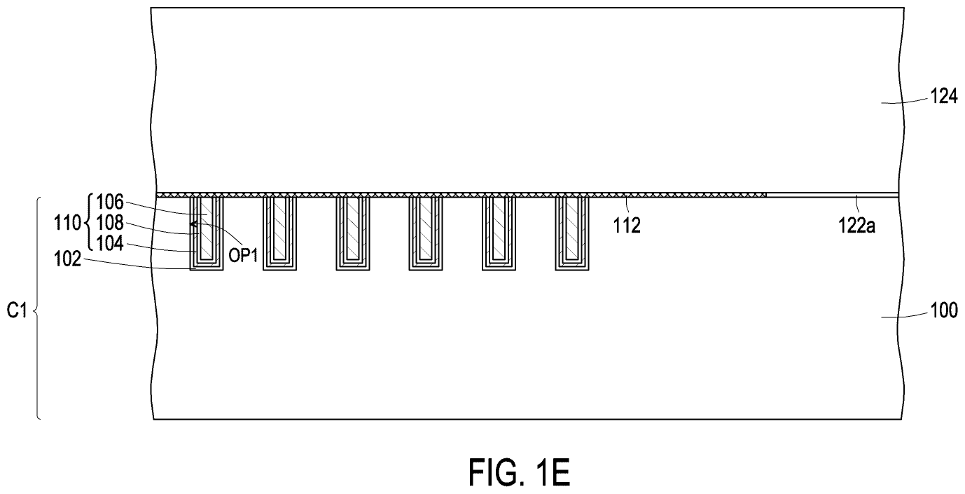

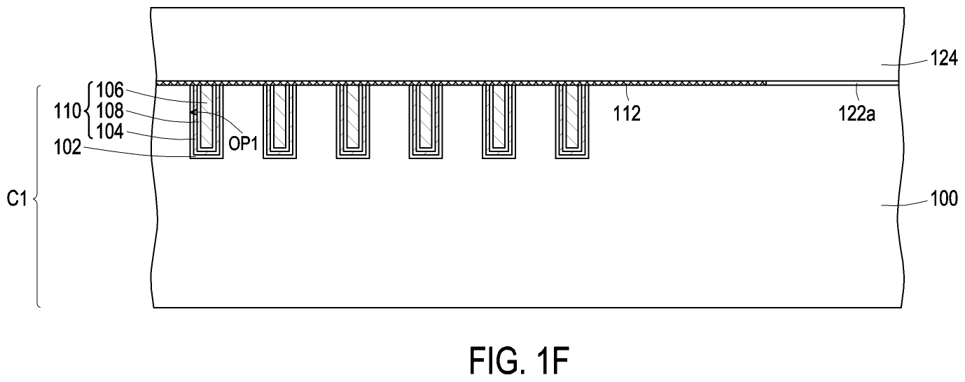

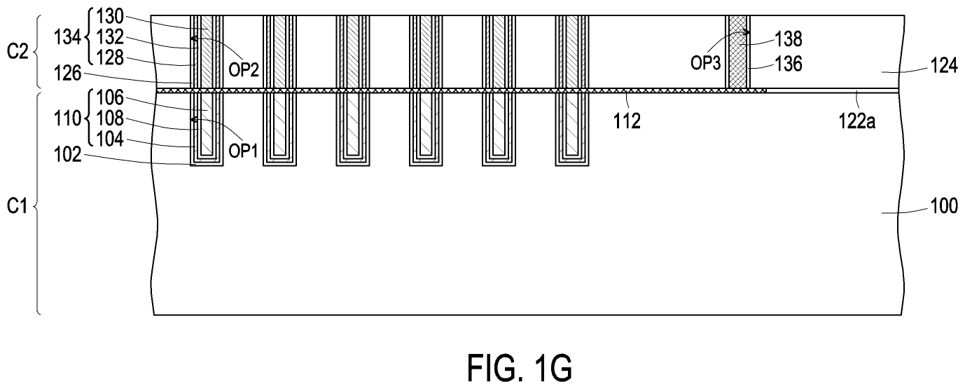

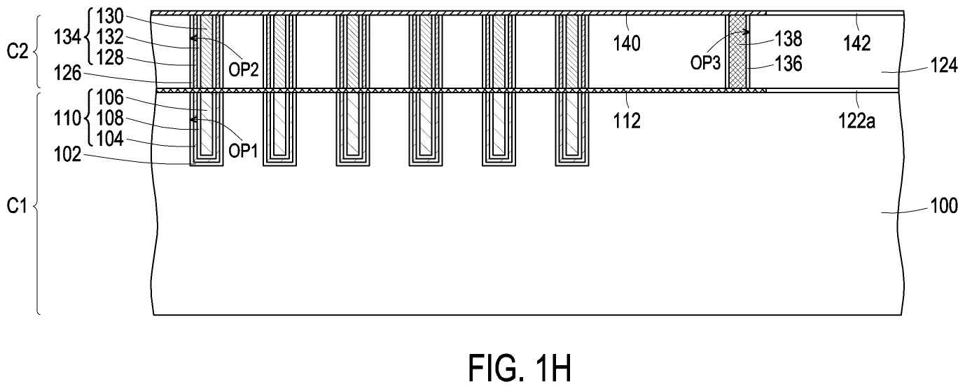

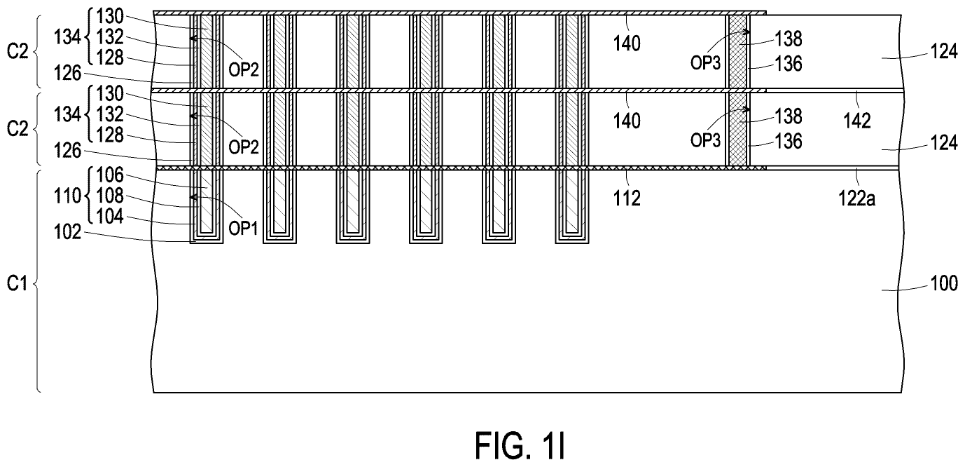

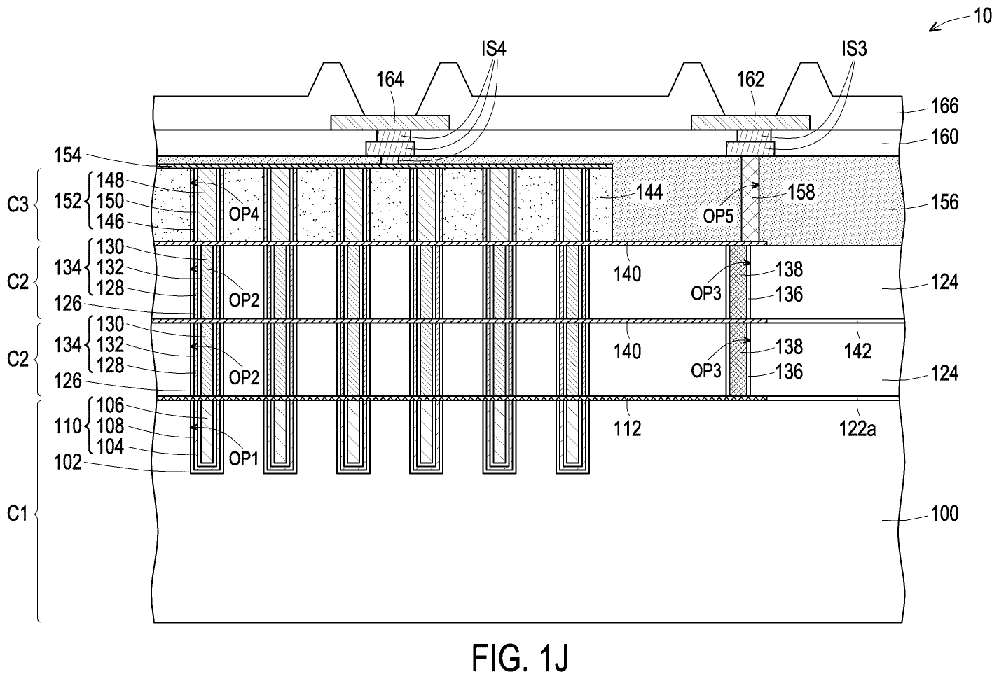

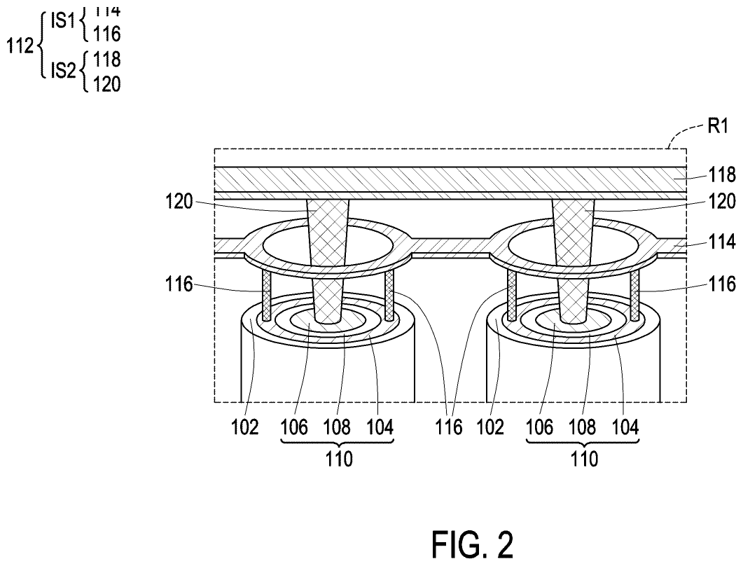

FIG. 1A to FIG. 1J are cross-sectional views of a manufacturing process of a capacitor structure according to some embodiments of the disclosure. FIG. 2 is a perspective view of a region R1 in FIG. 1B. In FIG. 2, some components in FIG. 1B are omitted to clearly describe an arrangement relationship between the components in FIG. 2.

Referring to FIG. 1A, a substrate 100 is provided. The substrate 100 may be a semiconductor substrate such as a silicon substrate. Next, multiple openings OP1 may be formed in the substrate 100. Afterwards, multiple dielectric layers 102, multiple electrode layers 104, multiple electrode layers 106, and multiple insulating layers 108 may be formed in the openings OP1. Thereby, a capacitor device structure C1 may be formed. The capacitor device structure C1 includes the substrate 100 and multiple capacitors 110. The capacitors 110 are located in the substrate 100. The capacitors 110 include the electrode layers 104, the electrode layers 106, and the insulating layers 108. The insulating layers 108 are located between the electrode layers 104 and the electrode layers 106. The capacitor device structure C1 may further include the dielectric layers 102. The dielectric layers 102 are located between the electrode layers 104 and the substrate 100. A material of the dielectric layer 102 is, for example, an oxide (such as silicon oxide). A material of the electrode layer 104 is, for example, titanium nitride (TiN) or titanium silicon nitride (TiSiN). A material of the electrode layer 106 is, for example, titanium nitride or titanium silicon nitride. A material of the insulating layer 108 is, for example, a dielectric material such as a high dielectric constant material.

Referring to FIG. 1B, a circuit layer 112 is formed on the capacitor device structure C1. The capacitors 110 may be connected in parallel by the circuit layer 112. In some embodiments, the circuit layer 112 may include multiple interconnect structures (such as an interconnect structure IS1 and an interconnect structure IS2 in FIG. 2) and a dielectric layer (not shown), where the interconnect structures may be located in the dielectric layer. In some embodiments, as shown in FIG. 2, the circuit layer 112 may include the interconnect structure IS1 and the interconnect structure IS2. The interconnect structure IS1 may include a conducting line 114 and multiple contacts 116. A material of the interconnect structure IS1 may include a conductive material such as copper, aluminum, or tungsten. The contacts 116 are electrically connected to the electrode layers 104, and the contacts 116 are electrically connected to the conducting line 114, whereby the electrode layers 104 may be electrically connected to each other. The interconnect structure IS2 may include a conducting line 118 and multiple contacts 120. A material of the interconnect structure IS2 may include a conductive material such as copper, aluminum, or tungsten. The contacts 120 are electrically connected to the electrode layers 106, and the contacts 120 are electrically connected to the conducting line 118, whereby the electrode layers 106 may be electrically connected to each other. The capacitors 110 may be connected in parallel by the interconnect structure IS1 and the interconnect structure IS2.

Referring to FIG. 1C, a dielectric material layer 122 may be formed on the circuit layer 112 and the capacitor device structure C1. A material of the dielectric material layer 122 is, for example, an oxide (such as silicon oxide), a nitride (such as silicon nitride), silicon oxynitride (SiON), or silicon nitride carbide (SiCN).

Referring to FIG. 1D, a chemical mechanical polishing (CMP) process may be performed on the dielectric material layer 122 to form a dielectric layer 122a on the capacitor device structure C1 and expose the circuit layer 112. The dielectric layer 122a may be connected to the circuit layer 112.

Referring to FIG. 1E, a substrate 124 may be bonded to the substrate 100. In some embodiments, a bonding method between the substrate 100 and the substrate 124 is, for example, a fusion bonding method. For example, the substrate 100 and the substrate 124 may be bonded by the dielectric layer 122a and a dielectric layer (not shown) of the circuit layer 112.

Referring to FIG. 1F, a thinning process may be performed on the substrate 124. In some embodiments, the thinning process is, for example, a grinding process, the chemical mechanical polishing process, or a combination thereof.

Referring to FIG. 1G, multiple openings OP2 may be formed in the substrate 124. Afterwards, multiple dielectric layers 126, multiple electrode layers 128, multiple electrode layers 130, and multiple insulating layers 132 may be formed in the openings OP2. Thereby, a capacitor device structure C2 may be formed on the circuit layer 112. The capacitor device structure C2 includes the substrate 124 and multiple capacitors 134. The capacitors 134 are located in the substrate 124. The capacitors 134 include the electrode layers 128, the electrode layers 130, and the insulating layers 132. The insulating layers 132 are located between the electrode layers 128 and the electrode layers 130. The capacitor device structure C2 may further include the dielectric layers 126. The dielectric layers 126 are located between the electrode layers 128 and the substrate 124. A material of the dielectric layer 126 is, for example, an oxide (such as silicon oxide). A material of the electrode layer 128 is, for example, titanium nitride or titanium silicon nitride. A material of the electrode layer 130 is, for example, titanium nitride or titanium silicon nitride. A material of the insulating layer 132 is, for example, a dielectric material such as a high dielectric constant material.

The electrode layers 128 may be electrically connected to each other by the circuit layer 112, and the electrode layers 130 may be electrically connected to each other by the circuit layer 112, whereby the capacitors 134 may be connected in parallel by the circuit layer 112. A method of electrically connecting the electrode layers 128 to each other and a method of electrically connecting the electrode layers 130 to each other may refer to a method of electrically connecting the electrode layers 104 to each other and a method of electrically connecting the electrode layers 106 to each other in FIG. 2, and are not described here again.

In addition, the electrode layers 104 and the electrode layers 128 may be electrically connected to each other by the circuit layer 112, and the electrode layers 106 and the electrode layers 130 may be electrically connected to each other by the circuit layer 112. For example, although not shown in the figure, the electrode layers 104 and the electrode layers 128 may be electrically connected to each other by the interconnect structure IS1, and the electrode layers 106 and the electrode layers 130 may be electrically connected to each other by the interconnect structure IS2. Therefore, the capacitors 110 and the capacitors 134 may be connected in parallel by the circuit layer 112.

In addition, an opening OP3 may be formed in the substrate 124. Afterwards, a dielectric layer 136 and a contact 138 may be formed in the opening OP3. The dielectric layer 136 is located between the contact 138 and the substrate 124. The contact 138 may be electrically connected to the circuit layer 112. A material of the dielectric layer 136 is, for example, an oxide (such as silicon oxide). The contact 138 may be a single-layer structure or a multi-layer structure. A material of the contact 138 is, for example, tungsten, titanium, titanium nitride, or a combination thereof.

Referring to FIG. 1H, a circuit layer 140 is formed on the capacitor device structure C2. In some embodiments, the circuit layer 140 may include the interconnect structures (not shown) and the dielectric layer (not shown), where the interconnect structures may be located in the dielectric layer. The relevant content of the circuit layer 140 may refer to the description of the circuit layer 112, and the description thereof is omitted here.

In addition, a dielectric layer 142 may be formed on the capacitor device structure C2. The dielectric layer 142 may be connected to the circuit layer 140. A material of the dielectric layer 142 is, for example, an oxide (such as silicon oxide), a nitride (such as silicon nitride), silicon oxynitride (SiON), or silicon nitride carbide (SiCN). In addition, a formation method of the dielectric layer 142 may refer to a formation method of the dielectric layer 122a, and the description thereof is omitted here.

Referring to FIG. 1I, the steps of forming the capacitor device structure C2, the dielectric layer 136, the contact 138, and the circuit layer 140 may be repeated at least one time to form multiple capacitor device structures C2, multiple dielectric layers 136, multiple contacts 138, and multiple circuit layers 140. The capacitors 134 of two adjacent capacitor device structures C2 may be connected in parallel by the circuit layer 140. The bonding method of two adjacent substrates 124 of the two adjacent capacitor device structures C2 is, for example, the fusion bonding method. For example, the two adjacent substrates 124 of the two adjacent capacitor device structures C2 may be bonded by a dielectric layer 142 and the dielectric layer (not shown) of the circuit layer 140. By the aforementioned method, at least one capacitor device structure C2, at least one dielectric layer 136, at least one contact 138, at least one circuit layer 140, and at least one dielectric layer 142 may be formed. In addition, the number of the capacitor device structures C2, the number of the dielectric layers 136, the number of the contacts 138, the number of the circuit layers 140, and the number of the dielectric layers 142 are not limited to the number shown in the figure. As long as the number of the capacitor device structures C2, the number of dielectric layers 136, the number of the contacts 138, the number of the circuit layers 140 and the number of the dielectric layers 142 are at least one, which falls within the scope of the disclosure.

Referring to FIG. 1J, a dielectric layer 144 may be formed on the circuit layer 140. A material of the dielectric layer 144 is, for example, an oxide (such as silicon oxide). Next, multiple openings OP4 may be formed in the dielectric layer 144. Afterwards, multiple electrode layers 146, multiple electrode layers 148, and multiple insulating layers 150 may be formed in the opening OP4s. Thereby, a capacitor device structure C3 may be formed on the circuit layer 140. The capacitor device structure C3 may include the dielectric layer 144 and multiple capacitors 152. The capacitors 152 are located in the dielectric layer 144. The capacitors 152 include the electrode layers 146, the electrode layers 148, and the insulating layers 150. The insulating layers 150 are located between the electrode layers 146 and the electrode layers 148. A material of the electrode layer 146 is, for example, titanium nitride or titanium silicon nitride. The material of the electrode layer 148 is, for example, titanium nitride or titanium silicon nitride. A material of the insulating layer 150 is, for example, a dielectric material such as a high dielectric constant material. In addition, the number of the capacitors 152 is not limited to the number shown in the figure.

The electrode layers 146 may be electrically connected to each other by the circuit layer 140, and the electrode layers 148 may be electrically connected to each other by the circuit layer 140, whereby the capacitors 152 may be connected in parallel by the circuit layer 140. A method of electrically connecting the electrode layers 146 to each other and a method of electrically connecting the electrode layers 148 to each other may refer to the method of electrically connecting multiple electrode layers 104 to each other and the method of electrically connecting the electrode layers 106 to each other in FIG. 2, and are not described here again.

In addition, the electrode layers 128 and the electrode layers 146 may be electrically connected to each other by the circuit layer 140, and the electrode layers 130 and the electrode layers 148 may be electrically connected to each other by the circuit layer 140. Therefore, the capacitors 134 and the capacitors 152 may be connected in parallel by the circuit layer 140.

Next, a circuit layer 154 may be formed on the capacitor device structure C3. In some embodiments, the circuit layer 154 may be electrically connected to the electrode layers 148. In other embodiments, the circuit layer 154 may be electrically connected to the electrode layers 146. In some embodiments, the circuit layer 140 may include the interconnect structures (not shown) and the dielectric layer (not shown), where the interconnect structures may be located in the dielectric layer.

Afterwards, a dielectric layer 156 may be formed on the capacitor device structure C2, the capacitor device structure C3, the circuit layer 140, and the circuit layer 154. Next, an opening OP5 may be formed in the dielectric layer 156. Moreover, a contact 158 may be formed in the opening OP5. The contact 158 may be electrically connected to the circuit layer 140. The contact 158 may be a single-layer structure or a multi-layer structure. A material of the contact 158 is, for example, tungsten, titanium, titanium nitride, or a combination thereof.

In addition, a dielectric layer 160 may be formed on the dielectric layer 156. An interconnect structure IS3 may be formed in the dielectric layer 160. The interconnect structure IS3 may be electrically connected to the contact 158. A interconnect structure IS4 may be formed in the dielectric layer 160 and the dielectric layer 156. The interconnect structure IS4 may be electrically connected to the circuit layer 154. A bonding pad 162 and a bonding pad 164 may be formed above the capacitor device structure C3. In this embodiment, the bonding pad 162 and the bonding pad 164 may be formed on the dielectric layer 160. The bonding pad 162 and the bonding pad 164 may be separated from each other. The bonding pad 162 may be electrically connected to the interconnect structure IS3. The bonding pad 164 may be electrically connected to the interconnect structure IS4. A protective layer 166 may be formed on the dielectric layer 160, the bonding pad 162, and the bonding pad 164. The protective layer 166 may expose a part of the bonding pad 162 and a part of the bonding pad 164.

Hereinafter, a capacitor structure 10 of the aforementioned embodiments is described with reference to FIG. 1J. In addition, a method of forming the capacitor structure 10 is described by taking the aforementioned method as an example, but the disclosure is not limited thereto.

Referring to FIG. 1J, the capacitor structure 10 includes the capacitor device structure C1, the circuit layer 112, and at least one capacitor device structure C2. In some embodiments, the capacitor structure 10 may be a chiplet structure. In some embodiments, the capacitor structure 10 may include a silicon capacitor structure. The capacitor device structure C1 includes the substrate 100 and the capacitors 110. The capacitors 110 are located in the substrate 100. The circuit layer 112 is located on the capacitor device structure C1. At least one capacitor device structure C2 is located on the circuit layer 112. The capacitor device structure C2 includes the substrate 124 and the capacitors 134. The capacitors 134 are located in the substrate 124. The capacitors 134 may penetrate the substrate 124. The capacitors 110 and the capacitors 134 are connected in parallel by the circuit layer 112, thereby effectively increasing the capacitance of the capacitor structure 10.

The capacitor structure 10 may further include at least one circuit layer 140. The circuit layer 140 is located on the capacitor device structure C2. In this embodiment, at least one capacitor device structure C2 may include the capacitor device structures C2, and at least one circuit layer 140 may include the circuit layers 140. The capacitor device structures C2 may be stacked on the circuit layer 112. The circuit layer 140 may be located between the two adjacent capacitor device structures C2. The capacitors 134 of the two adjacent capacitor device structures C2 may be connected in parallel by the circuit layer 140, thereby further increasing the capacitance of the capacitor structure 10.

The capacitor structure 10 may further include the dielectric layer 122a and the dielectric layer 142. The dielectric layer 122a is located between the substrate 100 and the substrate 124 of the lowermost capacitor device structure C2. The dielectric layer 142 is located between the two adjacent substrates 124 of the two adjacent capacitor device structures C2.

The capacitor structure 10 may further include the capacitor device structure C3. The capacitor device structure C3 is located on circuit layer 140. The capacitor device structure C3 may include the dielectric layer 144 and the capacitors 152. The capacitors 152 are located in the dielectric layer 144. The capacitors 152 may penetrate the dielectric layer 144. The capacitors 134 and the capacitors 152 may be connected in parallel by the circuit layer 140, thereby further increasing the capacitance of the capacitor structure 10. The capacitor structure 10 may further include the circuit layer 154. The circuit layer 154 is located on the capacitor device structure C3.

The capacitors 110 include the electrode layers 104, the electrode layers 106, and the insulating layers 108. The insulating layers 108 are located between the electrode layers 104 and the electrode layers 106. The capacitors 134 include the electrode layers 128, the electrode layers 130, and the insulating layers 132. The insulating layers 132 are located between the electrode layers 128 and the electrode layers 130. The capacitors 152 include the electrode layers 146, the electrode layers 148, and the insulating layers 150. The insulating layers 150 are located between the electrode layers 146 and the electrode layers 148. The capacitor device structure C1 may further include the dielectric layers 102. The dielectric layers 102 are located between the electrode layers 104 and the substrate 100. The capacitor device structure C2 may further include the dielectric layers 126. The dielectric layers 126 are located between the electrode layers 128 and the substrate 124.

The capacitor structure 10 may further include the bonding pad 162 and the bonding pad 164. The bonding pad 162 and the bonding pad 164 are located above the capacitor device structure C3 and are separated from each other. The capacitor structure 10 may further include the dielectric layer 156, the contact 138, the contact 158, the dielectric layer 136, the dielectric layer 160, the interconnect structure IS3, and the interconnect structure IS4. The dielectric layer 156 is located on the capacitor device structure C2, the capacitor device structure C3, the circuit layer 140, and the circuit layer 154. The contact 138 and the contact 158 are located in the substrate 124 and the dielectric layer 156 respectively. The circuit layer 112, the contact 138, the circuit layer 140 and the contact 158 may be electrically connected to each other. The dielectric layer 136 is located between the contact 138 and the substrate 124. The dielectric layer 160 is located on the dielectric layer 156. The bonding pad 162 and the bonding pad 164 are located on the dielectric layer 160. The interconnect structure IS3 is located in the dielectric layer 160. The interconnect structure IS3 may be electrically connected to the contact 158 and the bonding pad 162. The interconnect structure IS4 is located in the dielectric layer 160 and the dielectric layer 156. The interconnect structure IS4 may be electrically connected to the circuit layer 154 and the bonding pad 164. The capacitor structure 10 may further include the protective layer 166. The protective layer 166 is located on the dielectric layer 160, the bonding pad 162, and the bonding pad 164. The protective layer 166 may expose the part of the bonding pad 162 and the part of the bonding pad 164.

In some embodiments, the electrode layers 104, the electrode layers 128, and the electrode layers 146 may be electrically connected to each other and may be electrically connected to the bonding pad 162, and the electrode layers 106, the electrode layers 130, and the electrode layers 148 may be electrically connected to each other and may be electrically connected to the bonding pad 164. In some embodiments, the electrode layers 104, the electrode layers 128, and the electrode layers 146 may be electrically connected to each other by the circuit layer 112, the contact 138, the circuit layer 140, the contact 158, and the interconnect structure IS3 and may be electrically connected to the bonding pad 162, and the electrode layers 106, the electrode layers 130, and the electrode layers 148 may be electrically connected to each other by the circuit layer 112, the circuit layer 140, the circuit layer 154, and the interconnect structure IS4 and may be electrically connected to the bonding pad 164.

In other embodiments, the electrode layers 104, the electrode layers 128, and the electrode layers 146 may be electrically connected to each other and may be electrically connected to the bonding pad 164, and the electrode layers 106, the electrode layers 130, the electrode layers 148 may be electrically connected to each other and may be electrically connected to the bonding pad 162. In other embodiments, the electrode layers 104, the electrode layers 128, and the electrode layers 146 may be electrically connected to each other by the circuit layer 112, the circuit layer 140, the circuit layer 154, and the interconnect structure IS4 and may be electrically connected to the bonding pad 164, and the electrode layers 106, the electrode layers 130, and the electrode layers 148 may be electrically connected to each other by the circuit layer 112, the contact 138, the circuit layer 140, the contact 158, and the interconnect structure IS3 and may be electrically connected to the bonding pad 162.

In addition, the details of each component of the capacitor structure 10 (such as materials and formation methods, etc.) have been described in detail in the aforementioned embodiments and are not described here again.

Based on the aforementioned embodiments, it can be known that in the capacitor structure 10 and the manufacturing method thereof, the capacitor device structure C1 and the capacitor device structure C2 are stacked, and the capacitors 110 in the capacitor device structure C1 and the capacitors 134 in the capacitor device structure C2 are connected in parallel by the circuit layer 112, thereby effectively increasing the capacitance of the capacitor structure. In addition, the capacitor 110 is embedded in the substrate 100, and the capacitor 134 is embedded in the substrate 124, so the collapse of the capacitor 110 and the capacitor 134 may be prevented. Furthermore, since the manufacturing process of the capacitor structure 10 is simple, the manufacturing process complexity may be effectively reduced.

Although the disclosure has been disclosed above by embodiments, they are not intended to limit the disclosure. Anyone with ordinary knowledge in the relevant technical field can make some changes and modifications without departing from the spirit and scope of the disclosure. Therefore, the protection scope of the disclosure shall be determined by the scope of the appended claims.

What is claimed is:

1. A capacitor structure, comprising:
a first capacitor device structure, comprising:
a first substrate; and
a plurality of first capacitors, located in the first substrate;
a first circuit layer, located on the first capacitor device structure; and
at least one second capacitor device structure, located on the first circuit layer, wherein the second capacitor device structure comprises:
a second substrate; and
a plurality of second capacitors, located in the second substrate, wherein the plurality of first capacitors and the plurality of second capacitors are connected in parallel by the first circuit layer.

2. The capacitor structure according to claim 1, further comprising:
at least one second circuit layer, wherein the second circuit layer is located on the second capacitor device structure.

3. The capacitor structure according to claim 2, further comprising:
a third capacitor device structure, located on the second circuit layer, wherein the third capacitor device structure comprises:
a first dielectric layer; and
a plurality of third capacitors, located in the first dielectric layer, wherein the plurality of second capacitors and the plurality of third capacitors are connected in parallel by the second circuit layer.

4. The capacitor structure according to claim 3, further comprising:
a third circuit layer, wherein the third circuit layer is located on the third capacitor device structure.

5. The capacitor structure according to claim 4, wherein
the plurality of first capacitors comprise a plurality of first electrode layers, a plurality of second electrode layers, and a plurality of first insulating layers,
the plurality of first insulating layers are located between the plurality of first electrode layers and the plurality of second electrode layers,
the plurality of second capacitors comprise a plurality of third electrode layers, a plurality of fourth electrode layers, and a plurality of second insulating layers,
the plurality of second insulating layers are located between the plurality of third electrode layers and the plurality of fourth electrode layers,
the plurality of third capacitors comprise a plurality of fifth electrode layers, a plurality of sixth electrode layers, and a plurality of third insulating layers, and
the plurality of third insulating layers are located between the plurality of fifth electrode layers and the plurality of sixth electrode layers.

6. The capacitor structure according to claim 5, wherein the first circuit layer comprises:
a first interconnect structure, wherein the plurality of first electrode layers and the plurality of third electrode layers are electrically connected to each other by the first interconnect structure; and
a second interconnect structure, wherein the plurality of second electrode layers and the plurality of fourth electrode layers are electrically connected to each other by the second interconnect structure.

7. The capacitor structure according to claim 5, wherein
the first capacitor device structure further comprises:
a plurality of second dielectric layers, located between the plurality of first electrode layers and the first substrate, and
the second capacitor device structure further comprises:
a plurality of third dielectric layers, located between the plurality of third electrode layers and the second substrate.

8. The capacitor structure according to claim 5, further comprising:
a first bonding pad and a second bonding pad, located above the third capacitor device structure and separated from each other.

9. The capacitor structure according to claim 8, wherein
the plurality of first electrode layers, the plurality of third electrode layers, and the plurality of fifth electrode layers are electrically connected to each other and are electrically connected to the first bonding pad, and
the plurality of second electrode layers, the plurality of fourth electrode layers, and the plurality of sixth electrode layers are electrically connected to each other and are electrically connected to the second bonding pad.

10. The capacitor structure according to claim 8, wherein
the plurality of first electrode layers, the plurality of third electrode layers, and the plurality of fifth electrode layers are electrically connected to each other and are electrically connected to the second bonding pad, and
the plurality of second electrode layers, the plurality of fourth electrode layers, and the plurality of sixth electrode layers are electrically connected to each other and are electrically connected to the first bonding pad.

11. The capacitor structure according to claim 8, further comprising:
a second dielectric layer, located on the second capacitor device structure, the third capacitor device structure, the second circuit layer, and the third circuit layer; and
a first contact and a second contact, located in the second substrate and the second dielectric layer respectively, wherein the first circuit layer, the first contact, the second circuit layer, and the second contact are electrically connected to each other.

12. The capacitor structure according to claim 11, further comprising:
a third dielectric layer, located between the first contact and the second substrate.

13. The capacitor structure according to claim 11, further comprising:
a third dielectric layer, located on the second dielectric layer, wherein the first bonding pad and the second bonding pad are located on the third dielectric layer;
a first interconnect structure, located in the third dielectric layer and electrically connected to the second contact and the first bonding pad; and
a second interconnect structure, located in the third dielectric layer and the second dielectric layer and electrically connected to the third circuit layer and the second bonding pad.

14. The capacitor structure according to claim 13, wherein
the plurality of first electrode layers, the plurality of third electrode layers, and the plurality of fifth electrode layers are electrically connected to each other by the first circuit layer, the first contact, the second circuit layer, the second contact, and the first interconnect structure and are electrically connected to the first bonding pad, and
the plurality of second electrode layers, the plurality of fourth electrode layers, and the plurality of sixth electrode layers are electrically connected to each other by the first circuit layer, the second circuit layer, the third circuit layer, and the second interconnect structure and are electrically connected to the second bonding pad.

15. The capacitor structure according to claim 13, wherein
the plurality of first electrode layers, the plurality of third electrode layers, and the plurality of fifth electrode layers are electrically connected to each other by the first circuit layer, the second circuit layer, the third circuit layer, and the second interconnect structure and are electrically connected to the second bonding pad, and
the plurality of second electrode layers, the plurality of fourth electrode layers, and the plurality of sixth electrode layers are electrically connected to each other by the first circuit layer, the first contact, the second circuit layer, the second contact, and the first interconnect structure and are electrically connected to the first bonding pad.

16. The capacitor structure according to claim 13, further comprising:
a protective layer, located on the third dielectric layer, the first bonding pad, and the second bonding pad and exposing a part of the first bonding pad and a part of the second bonding pad.

17. The capacitor structure according to claim 2, wherein the at least one second capacitor device structure comprises a plurality of second capacitor device structures, the plurality of second capacitor device structures are stacked on the first circuit layer, the second circuit layer is located between two adjacent second capacitor device structures, and the second capacitor of the two adjacent second capacitor device structures are connected in parallel by the second circuit layer.

18. The capacitor structure according to claim 17, further comprising:
a second dielectric layer, located between the first substrate and the second substrate of the lowermost second capacitor device structure; and
a third dielectric layer, located between two adjacent second substrates of the two adjacent second capacitor device structures.

19. The capacitor structure according to claim 1, wherein
the plurality of first capacitors comprise a plurality of first electrode layers, a plurality of second electrode layers, and a plurality of first insulating layers,
the plurality of first insulating layers are located between the plurality of first electrode layers and the plurality of second electrode layers,
the plurality of second capacitors comprise a plurality of third electrode layers, a plurality of fourth electrode layers, and a plurality of second insulating layers, and
the plurality of second insulating layers are located between the plurality of third electrode layers and the plurality of fourth electrode layers.

20. The capacitor structure according to claim 19, wherein
a first interconnect structure, wherein the plurality of first electrode layers and the plurality of third electrode layers are electrically connected to each other by the first interconnect structure; and
a second interconnect structure, wherein the plurality of second electrode layers and the plurality of fourth electrode layers are electrically connected to each other by the second interconnect structure.
